(19) United States
(12) Patent Application Publication
(10) Pub. No.: US 2014/0225252 A1
(43) Pub. Date: Aug. 14, 2014

(54) ON-TRACK REVERSE LITHOGRAPHY TO THIN MASK FOR FABRICATION OF DARK-FIELD FEATURES

(71) Applicant: BREWER SCIENCE INC., Rolla, MO (US)

(72) Inventors: Qin Lin, Rolla, MO (US); Daniel M. Sullivan, Rolla, MO (US); Tony D. Flaim, St. James, MO (US); Yubao Wang, Rolla, MO (US); Jamie Lea Storie, St. James, MO (US)

(73) Assignee: BREWER SCIENCE INC., Rolla, MO (US)

(21) Appl. No.: 13/765,429

(22) Filed: Feb. 12, 2013

(51) Int. Cl. H01L 21/308; H01L 23/498; H01L 21/768

(52) U.S. Cl. CPC H01L 21/308; H01L 21/76885; H01L 23/49811
USPC 257/737; 438/613

(57) ABSTRACT

A reversal lithography approach is disclosed in which dark-field features are created on microelectronic substrates using bright-field lithography processes and a pattern reversal method. A wafer stack having a patterned imaging layer is provided that has a plurality of features formed thereon. A pattern reversal composition is applied to the patterned imaging layer overcoating the features, followed by wet etch-back of partially cured portions of the composition to expose the tops of the features. The imaging layer is then removed resulting in reversal of the pattern into the pattern reversal composition. This reversed pattern is then transferred into subsequent layers

### BACKGROUND

1. Field of the Invention

The present disclosure relates to reverse lithography methods that provide a competitive means to fabricate dark-field features.

2. Description of Related Art

As the semiconductor industry continues to advance rapidly, conventional lithography methods to shrink features by means of reducing the size of the mask pattern cannot progress fast enough to keep up with the industry roadmap. Some alternative methods have been developed to push the progress of photolithography. For bright-field lithography, it is straightforward to shrink features such as lines or pillars simply by overexposing. Moreover, features can be trimmed by dry etching to reduce their widths. Those technologies can be effective for features having sizes down to 22 nm and beyond. It is more difficult to shrink dark-field features, such as trenches, vias, or contact holes, and an effective method to fabricate dark-field features is urgently needed to match the progress of bright-field lithography.

In current integrated circuit production, trenches, vias, and contact holes are fabricated using dark-field lithography, which is facing serious technical difficulties in retaining good critical dimension (CD) control when the features are 45 nm or smaller. A cost- and technology-effective alternative for making dark-field features is urgently needed.

### SUMMARY

The present disclosure is broadly concerned with methods of forming microelectronic structures using a reversal lithography approach in which dark-field features are created on microelectronic substrates using bright-field lithography processes and a novel pattern reversal method. In general, a wafer stack having a patterned imaging layer is provided that has a plurality of features formed thereon. A pattern reversal composition is applied to the patterned imaging layer overcoating the features, followed by wet etch-back to expose the tops of the features. The imaging layer is then removed, resulting in reversal of the pattern into the pattern reversal composition. This reversed pattern is then transferred into subsequent layers.

In one or more embodiments, the methods generally comprise providing a patterned wafer stack, applying a pattern reversal composition to the stack, and contacting the pattern reversal layer with a wet etchant to remove portions of the pattern reversal layer, followed by removing portions of the original pattern to reverse the pattern into the pattern reversal layer. The reversed pattern can then be transferred into underlying layers and ultimately the substrate. The patterned wafer stack comprises a substrate having a surface, one or more intermediate layers optionally formed on the substrate surface, and a pattern comprising a plurality of raised features on the intermediate layers, if present, or on the substrate surface if no intermediate layers are present. The plurality of raised features are formed from a patterned imaging layer, and each feature is defined by respective sidewalls and a top surface. When applied, the pattern reversal composition is deposited between the plurality of features and overcoats the top surfaces of the plurality of features to form a partially conformal pattern reversal layer adjacent the pattern. The pattern reversal composition comprises a compound dispersed or dissolved in a solvent system. The partially conformal pattern reversal layer is contacted with a wet etchant to remove portions of the pattern reversal layer adjacent the top surfaces thereby exposing the top surfaces of the features to yield an etched-back pattern reversal layer. The pattern is reversed by removing the raised features that were exposed during the etch-back process to yield a reversed pattern in the etched-back pattern reversal layer. As noted above, the pattern can then be transferred into underlying portions of the stack.

A microelectronic structure is also described herein. The structure comprises a substrate having a surface, one or more intermediate layers optionally formed on the substrate surface, a pattern comprising a plurality of raised features on the intermediate layers, if present, or on the substrate surface if no intermediate layers are present, and a partially conformal pattern reversal layer adjacent the pattern. In the pattern, the plurality of raised features are formed from a patterned imaging layer, and are each defined by respective sidewalls and a top surface. The pattern reversal layer is formed from a pattern reversal composition deposited between the plurality of features and overcoating the top surfaces of the plurality of features.

### BRIEF DESCRIPTION OF THE DRAWINGS

Figures (FIG. 1 (A)-(G) are schematic drawings depicting a structure (not to scale) formed by the inventive process;

FIG. 2 is a scanning electron microscope (SEM) photograph showing a cross-sectional view of a patterned stack formed in Example 2;

FIG. 3 is an SEM photograph showing a cross-sectional view of the substrate with a pattern reversal composition deposited onto the patterned photoresist, as described in Example 2;

FIG. 4 is an SEM photograph showing a cross-sectional view of the substrate with a pattern reversal composition deposited onto the patterned photoresist, and then etched back, as described in Example 2;

FIG. 5 is an SEM photograph showing a cross-sectional view of the substrate with the original photoresist pattern removed using dry etching, as described in Example 3;

FIG. 6 is an SEM photograph showing a cross-sectional view of the substrate with the original photoresist pattern removed using liquid developer, as described in Example 4;

FIG. 7 is an SEM photograph showing a cross-sectional view of the substrate with the reversed pattern being transferred into subsequent layers, as described in Example 5;

FIG. 8 is an optical microscope photograph showing a patterned template formed using a negative tone developed photoresist, as described in Example 6; and

FIG. 9 is an optical microscope photograph showing the reversed pattern from FIG. 8, as described in Example 6.

### DETAILED DESCRIPTION

A preferred embodiment of the present invention is described in detail below with reference to FIGS. 1(A)-(G). While the drawings illustrate, and the specification describes, certain preferred embodiments of the invention, it is to be understood that such disclosure is by way of example only. Embodiments of the present invention are described herein with reference to cross-section illustrations that are schematic illustrations of idealized embodiments of the present invention. As such, variations from the shapes of the illustrations as a result, for example, of manufacturing techniques and/or tolerances, are to be expected. There is no intent to limit the principles of the present invention to the particular disclosed embodiments. For example, in the drawings, the size and relative sizes of layers and regions may be exaggerated for clarity. In addition, embodiments of the present invention should not be construed as limited to the particular shapes of regions illustrated herein but are to include deviations in shapes that result, for example, from manufacturing. For example, an etched region illustrated as a rectangle may have rounded or curved features. Thus, the regions illustrated in the figures are schematic in nature and their shapes are not intended to illustrate the precise shape of a region of a device and are not intended to limit the scope of the present invention, unless otherwise indicated.

### Methods of the Invention

In more detail, referring to FIG. 1(A), a substrate 10 having a surface 10a is provided. Any microelectronic substrate 10 can be used in the invention. Exemplary substrates 10 include those selected from the group consisting of silicon, SiGe, SiO₂, Si₃N₄, aluminum, tungsten, tungsten silicide, gallium arsenide, germanium, tantalum, tantalum nitride, coral, black diamond, phosphorous or boron doped glass, and mixtures of the foregoing. One or more intermediate layers 12 can be optionally formed on the substrate surface 10a. Suitable intermediate layers 12 are selected from the group consisting of anti-reflective layers, spin-on carbon (SOC) layers, amorphous carbon layers, hardmask layers, planarization layers, and combinations thereof. When anti-reflective layers are used, the intermediate layer 12 preferably has a thickness of from about 10 nm to about 50 nm, and more preferably from about 20 nm to about 40 nm. When spin-on carbon layers are used, the intermediate layer 12 preferably has a thickness of from about 50 nm to about 300 nm, and more preferably from about 100 nm to about 200 nm. When hardmask layers are used, the intermediate layer 12 preferably has a thickness of from about 10 nm to about 50 nm, and more preferably from about 20 nm to about 40 nm. Regardless, the substrate 10 can comprise a planar surface, or it can include topography (via holes, contact holes, pillars, trenches, lines, raised features, etc.). As used herein, “topography” refers to the height or depth of a structure in or on a substrate surface.

A photosensitive composition can then be applied to the intermediate layer 12, if present, or to the substrate surface 10a, if no intermediate layers 12 are present to form an imaging layer 14 on the stack 16. The resulting stack 16 is depicted in FIG. 1(A). It will be appreciated that multiple intermediate layers 12 (in various combinations) could also be used, with the imaging layer 14 being formed on the uppermost intermediate layer 12. Suitable photosensitive compositions for use as the imaging layer 14 include any compositions that can be patterned upon exposure to at least about 1 mJ/cm², such as photoresists, anti-reflective imaging layers, and the like. The imaging layer 14 can then be post-application baked (“PAB”) at a temperature of at least about 80° C., preferably from about 100° C. to about 140° C., and for time periods of from about 10 seconds to about 120 seconds (preferably from about 30 seconds to about 60 seconds). The thickness of the imaging layer 14 is preferably from about 10 nm to about 300 nm, more preferably from about 20 nm to about 150 nm, and even more preferably from about 30 nm to about 100 nm.

As depicted in FIG. 1(B), the imaging layer 14 can then be patterned, for example, by exposure to radiation (light) of the appropriate wavelength, followed by development of the exposed portions of the imaging layer 14. In one embodiment, as shown in FIG. 1(B), the imaging layer 14 is exposed using a mask 18 positioned above the imaging layer 14. The mask 18 has open areas 18a designed to permit radiation (hv) to pass through the mask 18 and contact the imaging layer 14 to yield exposed portions of the imaging layer that are rendered developer soluble. The remaining solid portions 18b of the mask 18 are designed to prevent radiation from contacting the imaging layer 14 in certain areas to yield unexposed portions of the imaging layer that remain developer soluble. Those skilled in the art will readily understand that the arrangement of open areas 18a and solid portions 18b is designed based upon the desired pattern to be formed in the imaging layer 14, although the present method is particularly suited for bright-field exposure where the majority of the imaging layer 14 is exposed to radiation to form raised features such as lines and pillars. After exposure, the imaging layer 14 is preferably subjected to a post-exposure bake (“PEB”) at a temperature of from about 80° C. to about 150° C., more preferably from about 100° C. to about 130° C., for a time period of from about 30 seconds to about 60 seconds.

Upon exposure, the portions of the imaging layer 14 that are exposed to radiation are rendered soluble in aqueous developer. As shown in FIG. 1(C), the exposed portions of the imaging layer 14 that were made soluble by the above process, are then contacted with an aqueous developer to remove the exposed portions to form the desired pattern 20 in the imaging layer 14. Alternatively, the exposed portions of the imaging layer 14 can be rendered insoluble during the exposure process, in which case, the removal process is reversed from what is described above. That is, the unexposed portions are removed during development to form the pattern (not shown). In either embodiment, at least about 95% of the exposed (or unexposed, as the case may be) portions of the imaging layer 14 will preferably be removed by the developer, more preferably at least about 99%, and even more preferably about 100% will be removed. Suitable developers are organic or inorganic alkaline solutions such as potassium hydroxide (KOH) and tetramethyl ammonium hydroxide (TMAH), and preferably comprise an aqueous solution of TMAH at a concentration of 0.26N or lower. Some of these developers are commercialized under the tradenames PD523AD (available from Moses Lake Industries, Inc., Moses Lake, Wash.), MF-319 (available from Shipley, Mass.), MF-320 (available from Shipley), and NMD3 (available from TOK, Japan).

FIG. 1(C) depicts the patterned stack 16′. The resulting pattern 20 preferably comprises raised features 14′ (e.g., lines, pillars, square islands, or combinations thereof) on the uppermost intermediate layer 12, when present, or substrate surface 10a, when no intermediate layers 12 are present. These features 14′ are each defined by respective sidewalls 14a and respective top surfaces 14b. It will be appreciated that in alternative embodiments, any other suitable patterning process may be used to pattern the imaging layer 14 and form raised features 14′, including multiple patterning processes, as well as immersion lithography. As mentioned above, it will also be appreciated that a negative-tone resist or photosensitive material could also be used, instead of the positive-tone imaging layer 14 described herein. In that case, the exposed portions of the imaging layer 14 are rendered insoluble, while the unexposed portions remain soluble and are removed with developer. Other patterning methods may also be used, including emerging technologies, such as imprint lithography, nano-imprint lithography, hot embossing lithography, and stamping pattern transfer. These technologies use a patterned mold to transfer patterns instead of relying on photolithographic patterning, as described above. The patterned imaging layer 14′ can also be achieved using a technique called positive tone photoresist negative tone develop (NTD), which involves the use of an organic solvent (such as, but not limited to, butyl acetate or 2-heptone) to remove the unexposed portions of a positive tone photoresist.

Regardless of the embodiment, the average (mean) feature size of the resulting raised features 14′ will preferably be less than about 200 nm, more preferably from about 1 nm to about 100 nm, even more preferably from about 5 nm to about 50 nm, and most preferably from about 10 nm to about 30 nm. The term “feature size,” as used herein, refers to the width “W” of the features as measured on an SEM cross-section of the substrate or layer 14 (thus in the case of pillars, the width is the same as the pillar diameter). It will be appreciated that techniques such as overexposure can be used to fabricate 32-nm or smaller features, which can be used as a template to be reversed into dark-field features (e.g., trenches and contact or via holes) that are 32 nm or smaller in size. Features of the pattern 20 may also be trimmed to further decrease their size, as desired, before proceeding with subsequent processing. The average (mean) height “H” of the features 14′ (which also corresponds to the thickness of the imaging layer 14; FIG. 1(C)) will preferably range from about 20 nm to about 500 nm, more preferably from about 20 nm to about 200 nm, and even more preferably from about 25 nm to about 100 nm.

Once the desired pattern is formed, as shown in FIG. 1(D), a pattern reversal composition 22 is applied to the patterned stack 16′, overcoating the top surfaces 14b of the raised features 14′, and forming a layer adjacent the uppermost intermediate layer 12 (or substrate surface 10a, as applicable) in the spaces between the raised features 14′. The pattern reversal composition 22 is preferably applied via spin coating at speeds of from about 800 rpm to about 5,000 rpm, preferably from about 1,000 rpm to about 3,000 rpm, and for time periods of from about 20 seconds to about 90 seconds, preferably from about 30 seconds to about 60 seconds. The pattern reversal composition 22 is then baked at a temperature sufficient to drive off solvents and effect a slight curing of the composition to yield a cured or dried pattern reversal mask 22. Preferably the pattern reversal composition 22 is baked at a temperature of less than about 140° C., preferably from about 80° C. to about 130° C., more preferably from about 90° C. to about 120° C., and even more preferably from about 100° C. to about 110° C., for a time period of from about 10 seconds to about 120 seconds, and preferably from about 30 seconds to about 60 seconds.

As depicted in FIG. 1(D), the pattern reversal composition 22 forms a partially conformal layer on the patterned stack 16′. In one or more embodiments, the partially conformal layer is not photosensitive. As used herein, the term “partially conformal,” means that the composition 22 flows into the spaces between the raised features 14′ (adjacent the intermediate layer 12 or substrate surface 10a), and forms a layer adjacent the sidewalls 14a and top surfaces 14b of the raised features 14′, but is not of a uniform thickness as measured in all directions, as a fully conformal layer would be. In other words, the layer is conformal in the sense that it does not form a planarizing layer over the raised features 14′, but instead accommodates the surface topography, but is not fully conformal to the raised features 14′, where a “fully conformal” layer is defined as one coated as a substantially uniform thickness on both horizontal and vertical surfaces of the topography. Thus, as depicted in FIG. 1(D), the thickness “t” of the pattern reversal composition 22 adjacent the top surfaces 14b of the raised features 14′ will be different (i.e., less and preferably substantially less) than the thickness “T” of the pattern reversal composition 22 adjacent the intermediate layers 12 (or substrate surface 10a, as applicable). More specifically, the thickness t of the pattern reversal mask 22 overcoat adjacent the top surfaces 14b is preferably less than about 40 nm, more preferably from about 2 nm to about 30 nm, and even more preferably from about 5 nm to about 20 nm. Thus, an ultra-thin film of the pattern reversal mask 22 is formed adjacent the top surfaces 14b. The thickness T of the pattern reversal mask 22 adjacent the intermediate layers 12 (or substrate surface 10, as applicable) is preferably from about 5 nm to about 100 nm, more preferably from about 10 nm to about 60 nm, and even more preferably from about 15 nm to about 45 nm. The thickness T of the pattern reversal composition 22 will also be different (i.e., less) than the height H of the features 14′. In some embodiments, the average difference between T and H (i.e., H minus T) will be at least about 10 nm, preferably at least about 20 nm, and more preferably from about 25 to about 30 nm.

In addition to thickness variations, the pattern reversal composition 22 overcoating adjacent the top surfaces 14b of the raised features 14′ remains only partially cured, whereas the bulk of the composition 22 in between the raised features 14′ and adjacent the intermediate layer 12 (or substrate surface 10a, as applicable) is cured and insoluble in solvents or developers. This is due to the interaction and poisoning of the pattern reversal composition 22 by the imaging layer 14, which results in a weaker film formation (and lower crosslinking density) adjacent the top surfaces 14b of the raised features 14′. The term “partially cured,” as used herein means that the degree of reaction is lower than the bulk part of the film (between features 14′) due to an interruption in crosslinking by the underlying features 14′. Thus, the partially cured portions of the reversal composition remain soluble in aqueous, weak basic, or organic solvents.

As depicted in FIG. 1(E), the stack 16′ can be subjected to a wet etching to etch back the pattern reversal composition 22, to remove a portion of the pattern reversal composition 22 and expose the top surfaces 14b of the raised features 14′. That is, there is preferably no dry etching carried out in the process to etch back the pattern reversal composition 22. Advantageously, the wet etching process can be carried out “on-track,” which means that the stack 16′ is etched on the same track used for patterning and application of the pattern reversal composition 22, without removing it from the track to other machinery to carry out the etching, as required in prior art etch-back processes. The wet etch-back process can be carried out by contacting the pattern reversal composition 22 with an etching solution for about 10 to about 120 seconds, preferably from about 20 to about 90 seconds, and more preferably from about 30 to about 60 seconds, at a temperature of from about 20° C. to about 60° C. (and preferably from about 21° C. to about 25° C.) to yield the wet etched-back composition 22′. The etching solution can be sprayed, puddled, or otherwise applied to the pattern reversal composition 22. Alternatively, the stack 16′ can be immersed in the etching solution. Suitable etching solutions include diluted photoresist developers (e.g., aqueous solution containing tetramethyl ammonium hydroxide from about 0.1 to about 25 wt %, preferably from about 0.5 to about 2.4 wt %, more preferably from about 0.7 to about 2.2 wt %), aqueous solvents (e.g., acetic acid solution), organic solvents commonly used in the semiconductor industry (e.g., ethyl lactate (EL), propylene glycol monomethyl ether (PGME), and propylene glycol methyl ether acetate (PGMEA) methyl isobutyl carbinol (MIBC), cyclopentanone), and mixtures thereof. In some embodiments, suitable etching solutions would not include strong (minimally or undiluted) base solutions. As noted above, since the pattern reversal composition 22 adjacent the top surfaces 14b of the raised features 14′ is only partially cured, it is easily removed in the wet etching process, exposing top surfaces 14b. In preferred embodiments, the pattern reversal composition 22 adjacent the top surfaces 14b of the raised features 14′ is completely removed during the wet etching process, without any further (wet or dry) etching, or other further processing required to completely expose the top surfaces 14b of the raised features 14′. In other words, thickness t′ of the the wet etched-back composition 22′ adjacent the top surfaces 14b of the raised features 14′ after wet etching will be less than about 2 nm, preferably less than about 1 nm, and more preferably about 0 nm after wet etching. Thus, the wet etched-back composition 22′ will only remain between raised features 14′ (adjacent intermediate layers 12 or substrate surface 10) and will be substantially (and preferably completely) absent from the top surfaces 14b. The thickness T′ of the wet etched-back composition 22′ in some embodiments will remain substantially the same as the thickness T of the pattern reversal composition 22 (FIG. 1(D)). In other embodiments, portions of the pattern reversal composition between raised features 14′ may be slightly removed during the wet etch-back process, such that the thickness T′ of the wet etched-back composition 22′ is less than the thickness T of the pattern reversal composition 22. In some embodiments, the thickness T′ of the wet etched-back composition 22′ is from about 5 nm to about 100 nm, preferably from about 10 nm to about 60 nm, and more preferably from about 15 nm to about 45 nm.

The raised features 14′ can then be removed, as shown in FIG. 1(F), and the etched-back pattern reversal composition 22′ can be used as a mask for transferring the reversed pattern into the subsequent layers. In one or more embodiments, the raised features 14′ can be removed by immersing the stack 16′ in a suitable solvent for a time period of from about 10 to about 170 seconds, and preferably for a time period of from about 30 to about 60 seconds, followed by spin drying at from about 800 rpm to about 5,000 rpm (preferably from about 1,000 rpm to about 3,000 rpm) for from about 10 to about 120 seconds (and preferably from about 30 seconds to about 60 seconds).

Suitable solvents for removing the raised features 14′ are selected from the group consisting of PGMEA, EL, cyclopentanone, cyclohexanone, gamma-butyrolactone, and mixtures thereof. Alternatively, the raised features 14′ can be removed using a dry etching process, such as an O₂ etching process. In a further embodiment, the raised features 14′ can be removed using a blanket exposure to radiation at the appropriate wavelength, followed by a PEB and developer wash, as described above for pattern formation. In some embodiments which involve NTD technology for pattern formation (discussed above), the wet etch-back and removal of the raised features 14′ can be combined into a single step using an aqueous base solution to etch back the pattern reversal composition 22 and subsequently remove the raised features 14′ as described above.

Regardless of the embodiment, removal of the raised features 14′ results in the reversal of the bright-field pattern 20 to create a reversed pattern 24 in the etched-back pattern reversal composition 22′, comprising reversed features such as trenches, spaces, and holes, traditionally created using a dark-field process. As shown in FIG. 1(F), the reversed features of the reversed pattern 24 correspond to the features 14′ formed from the patterned imaging layer 14 and will have the same average feature size, “W′,” as discussed above with respect to the feature size, “W,” of the raised features 14′. The reversed features also preferably have the same line roughness (or smoothness) as the raised features 14′.

As shown in FIG. 1(G), an etching process (wet or dry) is then used to transfer the reversed pattern 24 from the etched-back pattern reversal composition 22′ into the intermediate layers 12, if present, and ultimately into the substrate 10 (not shown), using the etched-back pattern reversal composition 22′ as a mask. In one or more embodiments, reactive ion etching (RIE) is used to transfer the reversed pattern 24 using a reactive ion plasma of CF₄, O₂, HBr, Cl₂, CHF₃, CH₃F₂, SF₆, mixtures thereof, or combinations (i.e., where the gas is changed during the etching process) thereof. In some embodiments, the etched-back pattern reversal composition 22′ is resistant to etching with O₂, and preferably etches at a rate of less than about 100 Å/min., more preferably less than about 50 Å/min., and even more preferably less than about 20 Å/min., when O₂, is used as the etchant. Thus, when the intermediate layer 12 is spin-on carbon, the etch selectivity of the etched-back pattern reversal composition 22′ over the intermediate layer 12 will be less than about 0.2, preferably less than about 0.1, and more preferably from about 0.01 to about 0.05, when O₂ is used as the etchant. The O₂ resistance also facilitates removal of the imaging layer 14′ via etching as described above.

In some embodiments, the etched-back pattern reversal composition 22′ is resistant to etching with CF₄, and preferably etches at a rate of less than about 10 Å/min., more preferably less than about 5 Å/min., and even more preferably less than about 2 Å/min., when CF₄ is used as the etchant. Thus, when the intermediate layer 12 is a hardmask, the etch selectivity of the reversal mask 22 over the intermediate layer 12 will be less than about 0.2, preferably less than about 0.1, and more preferably from about 0.01 to about 0.05, when CF₄ is used as the etchant.

It will be appreciated that multiple intermediate layers 12, each with different etch selectivities, can be used to facilitate transfer of the reversed pattern 24 into the underlayers and eventually the substrate. For example, a bottom layer of a thick organic under layer and a top layer of thin spin-on hardmask could be used. A spin-on hardmask typically etches faster in CF₄, and a CF₄ etch can be used to transfer the reversed pattern 24 in the etched-back pattern reversal composition 22′ to the hardmask layer. The pattern 24 can then be transferred to the thick organic underlayer using an O₂ etch. Other suitable pattern transfer techniques can also be used.

### Pattern Reversal Compositions for Use in the Invention

The pattern reversal compositions for use in forming the reversal mask of the invention preferably comprise a compound dispersed or dissolved in a solvent system. Suitable compounds include monomers, oligomers, polymers, sol-gel compounds, nanoparticles, and combinations of the foregoing. Typical examples of the reversal compounds include silicon-containing compounds, such as silicates (e.g., tetraethyl orthosilicate (TEOS)), compounds of the formula R—Si(OR)₃, where each R is an organic functional group individually selected from the group consisting of alkyls (C₁-C₂₀, preferably C₁-C₁₀), benzene, substituted derivatives thereof, and combinations thereof. In one or more embodiments, a copolymer of TEOS and compounds of the formula R—Si(OR)₃, as defined above, can be used. The compound is present in the composition at a level of from about 0.1% to about 10% by weight, more preferably from about 0.2% to about 7% by weight, and even more preferably from about 0.5% to about 5% by weight, based upon the total weight of the composition taken as 100% by weight.

The solvent system should be selected so that it does not disrupt or dissolve the pattern 20 formed in the imaging layer 14. Suitable solvents for use in the solvent system include water, mesitylene, MIBC, PGMEA, PGME, and mixtures thereof. The solvent system is preferably used in the composition at a level of from about 90% to about 99.9% by weight, more preferably from about 93% to about 99.8% by weight, and even more preferably from about 95% to about 99.5% by weight, based upon the total weight of the composition taken as 100% by weight. The total solids of the composition can range from about 0.1% to about 10% by weight, more preferably from about 0.2% to about 7% by weight, and even more preferably from about 0.5% to about 5% by weight, based upon the total weight of the composition taken as 100% by weight.

The compositions can further comprise a catalyst, such as ammonium salt. When present, the catalyst is preferably used in the composition at a level of from about 0.01% to about 5% by weight, more preferably from about 0.02% to about 3% by weight, and even more preferably from about 0.05% to about 1% by weight, based upon the total weight of the composition taken as 100% by weight. The composition can also include additives such as surfactants, and the like.

The composition is formed by simply mixing the compound and any other ingredients in the solvent system. These materials can be cured at a suitable temperature in the presence of a catalyst, and they can also be wet etched using a basic solution, as described above. In one or more embodiments, the compositions are not photosensitive and do not undergo chemical or physical changes upon exposure to light. For example, in some embodiments, the cured compositions are not developer soluble and cannot be rendered developer-soluble upon exposure to light,

Additional advantages of the various embodiments of the disclosure will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments, but is not necessarily included. Thus, the present invention encompasses a variety of combinations and/or integrations of the specific embodiments described herein.

The present description also uses numerical ranges to quantify certain parameters relating to various embodiments of the invention. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the invention. It is to be understood, however, that these examples are provided by way of illustration and nothing therein should be taken as a limitation upon the overall scope of the invention.

### Example 1

### Preparation of Pattern Reversal Composition and Wet-Etching Solution

A pattern reversal composition was preparing by diluting a silicon-containing polymer solution (10% by weight TEOS sol-gel copolymer in PGMEA; OptiStack® HM710; Brewer Science Inc., Rolla, Mo.) to 1.6 wt % with methyl isobutyl carbinol (MIBC; Aldrich, St. Louis, Mo.). The solution was then filtered using a 100-nm polytetrafluoroethylene (PTFE) filter to yield the pattern reversal composition.

A wet-etching solution was prepared by adding 30 grams of an aqueous alkaline photoresist developer (0.26N TMAH in water; PD523AD) into 70 grams of deionized water.

### Example 2

### Formation of Bright-Field Patterned Template

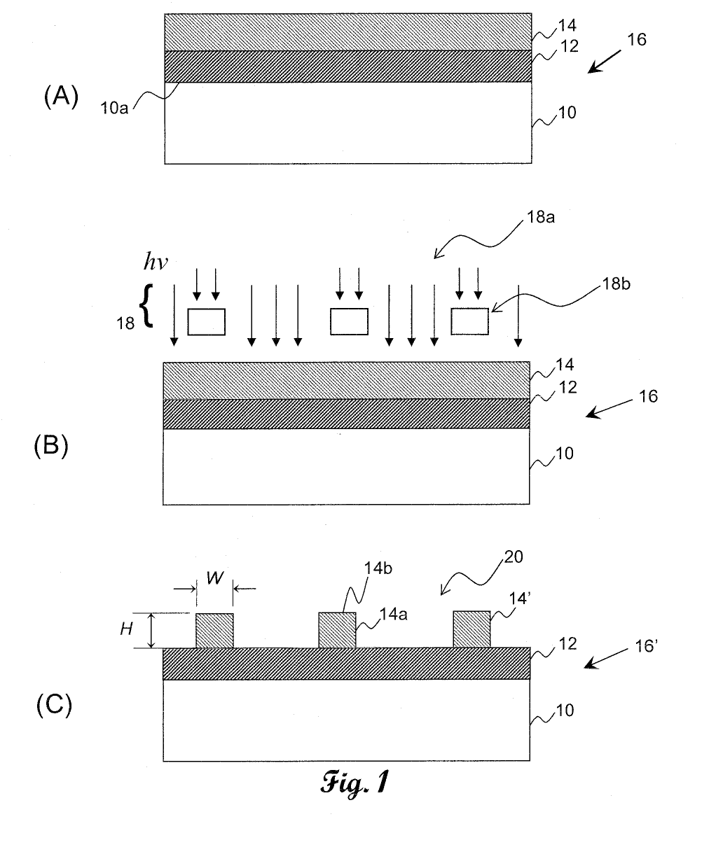

A wafer stack was prepared by forming a bottom layer of a spin-on carbon composition (OptiStack® SOC 110; Brewer Science Inc.) on a silicon wafer. Next, a silicon-containing antireflective hardmask (OptiStack® HM710) was applied on top of the SOC layer. A photoresist layer (Pi-6001; TOK America, Hillsboro, Oreg.) was formed on top of the hardmask layer, followed by bright-field patterning (i.e., exposure and development) of the photoresist to form raised lines with a pitch of 1:3 (FIG. 2). These bright-field features were used as the template for forming a reversed dark-field pattern.

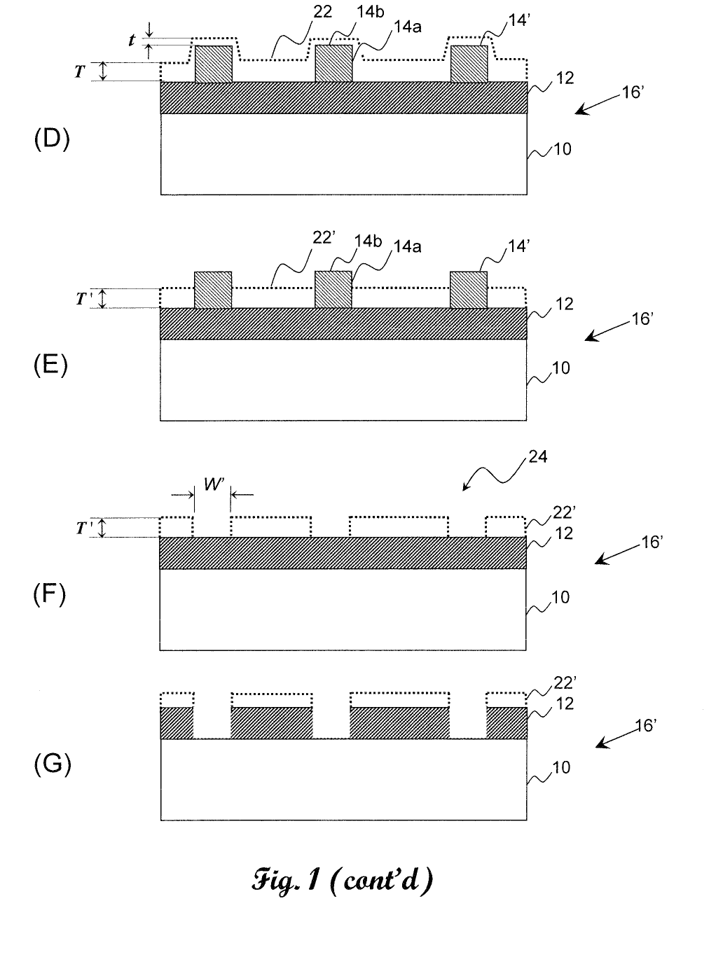

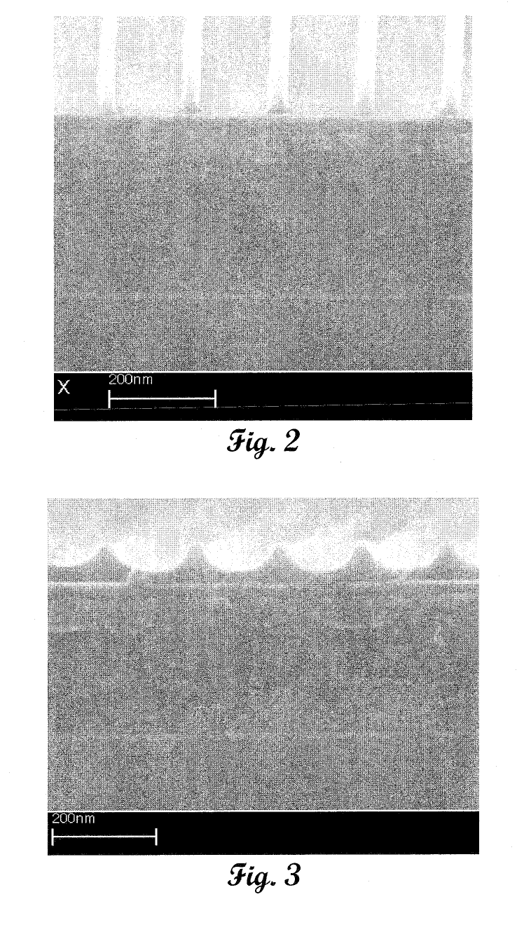

The pattern reversal composition prepared in Example 1 was then coated onto the patterned stack, followed by baking at 100° C. for 60 seconds. The SEM photo in FIG. 3 shows a thin coating (˜25 nm) adjacent the hardmask layer between two photoresist lines, and a very thin overcoating covering the tops and sidewalls of the photoresist lines.

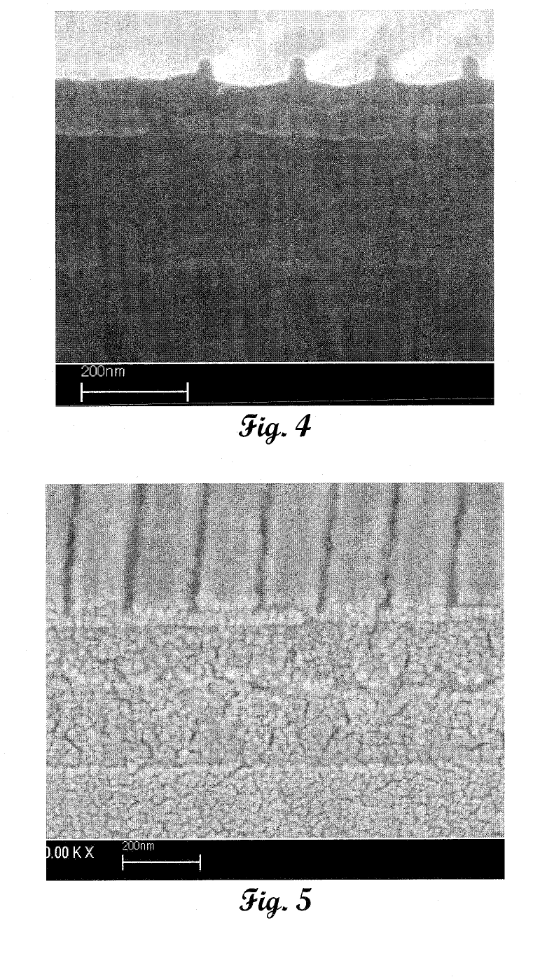

The stack was then immersed into the wet-etching solution prepared in Example 1 for 60 seconds, followed by rinsing with deionized water, and spin-drying. The SEM photo in FIG. 4 shows that the reversal composition overcoating on top of the photoresist lines was removed by the wet-etching process, exposing the tops of the photoresist lines, while a thin layer of reversal material remains between the photoresist lines, adjacent the hardmask layer.

### Example 3

### Photoresist Removal with Dry Etching

In this Example, dry etching was used to remove the photoresist lines faulted using bright-field lithography in Example 2. The exposed photoresist lines were dry etched with O₂ plasma using an Oxford Plasmalab reactive ion etcher (conditions: 100 watts of power, 50-mTorr pressure, 3-mTorr backside helium pressure, 50-sccm gas flow rate) for 30 seconds. The SEM picture in FIG. 5 shows that the original photoresist lines that had been exposed through the wet etch-back in Example 2 were removed, and the bright-field pattern was reversed into trenches formed in the pattern reversal layer.

### Example 4

### Photoresist Removal with Developer

In this Example, a TMAH-based liquid developer (PD523AD) was used to remove the photoresist lines formed using bright-field lithography in Example 2. After the wet etch-back in Example 2, the stack was exposed under broadband ultraviolet light (18 mJ/cm²) for 5 seconds and baked at 100° C. for 60 seconds. The stack was then immersed into the developer for 60 seconds, rinsed with deionized water, and spin-dried. The SEM picture in FIG. 6 shows that the original photoresist lines were removed and the bright-field pattern was reversed into trenches formed in the pattern reversal layer.

### Example 5

### Pattern Transfer to Underlayer

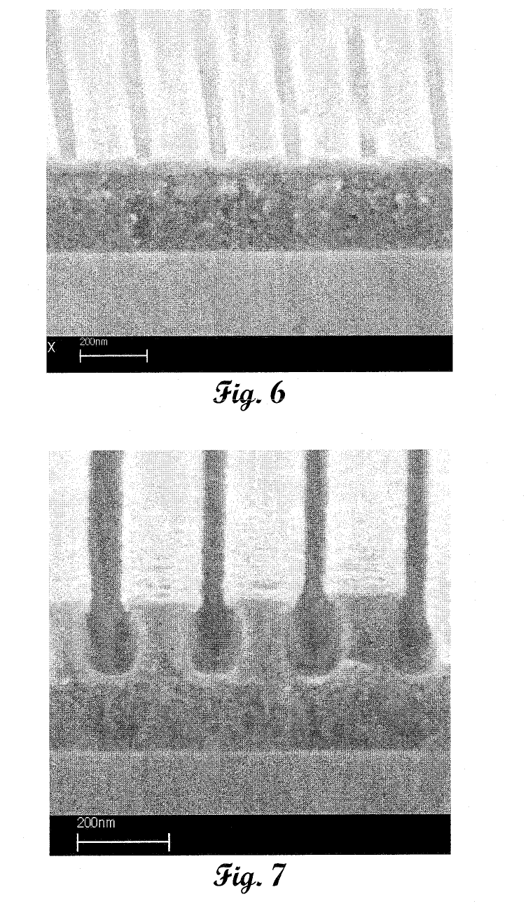

The stack from Example 4 was etched using a reactive ion plasma of CF₄ (35 sccm; power—100 W; pressure—100 mTorr) using an Oxford Plasmalab RIE for 30 seconds to transfer the trench pattern into the hardmask layer using the pattern reversal layer as a mask. Next, the etching was continued down into the SOC layer by switching to O₂ (50 sccm; power—100 W; pressure—100 mTorr) for 60 seconds using the hardmask layer as a mask. The resulting patterned stack is shown in FIG. 7.

### Example 6

### Positive Tone Photoresist Negative Tone Development (NTD) Patterning

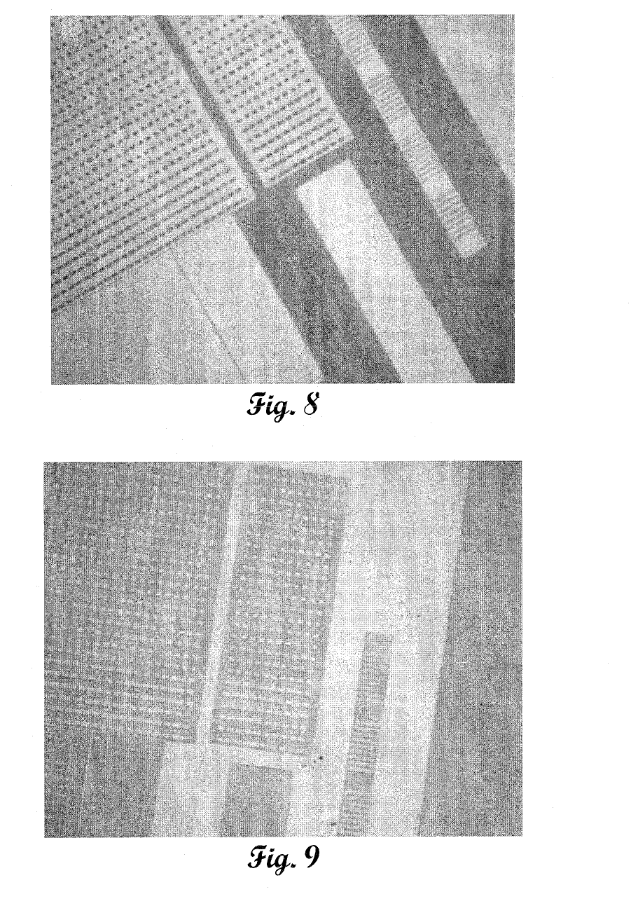

A wafer stack was prepared by forming a bottom layer of a spin-on carbon composition (OptiStack® SOC 110; Brewer Science Inc.) on a silicon wafer. Next, a silicon-containing bottom anti-reflective coating/hardmask layer (OptiStack® HM9822; Brewer Science, Inc.) was applied on top of the SOC layer. An NTD photoresist layer (FAIRS9521-V10K, North Kingstown, R.I.) was then formed on top of the hardmask layer. The photoresist was then patterned using exposure followed by negative-tone development of the positive tone photoresist using organic solvents. The NTD technique uses bright-field imaging to produce the line/space patterns. Instead of using a developer to remove the exposed (developer-soluble) portions of the photoresist, an organic solvent (e.g., PGMEA, cyclopentanone) was used to remove the unexposed portions of the photoresist. The resulting pattern as viewed under an optical microscope is shown in FIG. 8.

The pattern reversal composition and wet-etch solution from Example 1 were then used to coat the features, followed by baking at 100° C. for 60 seconds, and then wet etch-back to expose the tops of the photoresist pattern. For wet etching, the stack was immersed into the etching solution for 60 seconds, rinsed with deionized water, and then spin-dried. The photoresist pattern was then removed as described above. The resulting reversed pattern formed in the reversal layer, as viewed under an optical microscope, is shown in FIG. 9.

We claim:

1. A method of forming a microelectronic structure, said method comprising:
providing a wafer stack, said stack comprising:
a substrate having a surface;
one or more intermediate layers optionally formed on said substrate surface; and
a pattern comprising a plurality of raised features on the intermediate layers, if present, or on the substrate surface if no intermediate layers are present, wherein said plurality of raised features are formed from a patterned imaging layer, said features each being defined by respective sidewalls and a top surface;
applying a pattern reversal composition to said stack, said pattern reversal composition being deposited between said plurality of features and overcoating said top surfaces of said plurality of features to form a partially conformal pattern reversal layer adjacent said pattern, said composition comprising a compound dispersed or dissolved in a solvent system;
contacting said pattern reversal layer with a wet etchant to remove portions of said pattern reversal layer adjacent said top surfaces thereby exposing said top surfaces of said features to yield an etched-back pattern reversal layer;
removing said raised features to yield a reversed pattern in said etched-back pattern reversal layer; and
transferring said reversed pattern into said intermediate layers, if present, or into said substrate if no intermediate layers are present.

2. The method of claim 1, wherein said providing comprises:
providing a substrate having a surface;
optionally forming one or more intermediate layers on said substrate surface;
applying a photosensitive composition to form an imaging layer on said intermediate layers, if present, or on said substrate surface if no intermediate layers are present; and
patterning said imaging layer to yield said pattern.

3. The method of claim 2, wherein said patterning comprises:
exposing said imaging layer to radiation to yield exposed portions of said imaging layer; and
contacting said imaging layer with a developer so as to remove said exposed portion.

4. The method of claim 2, wherein said patterning comprises:
exposing said imaging layer to radiation to yield exposed and unexposed portions of said imaging layer; and
contacting said imaging layer with an organic solvent so as to remove said unexposed portions.

5. The method of claim 1, wherein said stack comprises one or more intermediate layers, said intermediate layers being selected from the group consisting of anti-reflective layers, spin-on carbon layers, amorphous carbon layers, hardmask layers, planarization layers, and combinations thereof.

6. The method of claim 1, wherein said raised average features are selected from the group consisting of lines, pillars, square islands, and combinations thereof.

7. The method of claim 1, wherein said raised features have respective feature sizes of less than about 200 nm.

8. The method of claim 1, wherein said reversed pattern comprises a plurality of reversed features selected from the group consisting of trenches, spaces, via holes, contact holes, and combinations thereof.

9. The method of claim 8, wherein said reversed features have respective feature sizes of less than about 200 nm.

10. The method of claim 1, wherein the thickness of said partially conformal layer between said raised features is greater than the thickness of said partially conformal layer adjacent said top surfaces of said raised features.

11. The method of claim 1, wherein the thickness of said partially conformal layer between said raised features is from about 5 to about 100 nm.

12. The method of claim 1, the thickness of said partially conformal layer adjacent said top surfaces is less than about 20 nm.

13. The method of claim 1, said raised features having a height, wherein the thickness of said partially conformal layer between said raised features is less than said height.

14. The method of claim 1, wherein said portions of said partially conformal layer adjacent said top surfaces of said raised features are partially cured.

15. The method of claim 1, wherein said partially conformal layer between said raised features is fully cured.

16. The method of claim 1, wherein said contacting is carried out on-track.

17. The method of claim 1, wherein no dry etching occurs prior to said removing.

18. The method of claim 1, wherein said compound is selected from the group consisting of silicates, compounds of the formula R—Si(OR)₃, substituted derivatives thereof, and combinations thereof, where each R is an organic functional group individually selected from the group consisting of alkyls, benzene, and combinations thereof.

19. The method of claim 1, wherein said removing is selected from the group consisting of: contacting said raised features with a solvent; and etching said raised features with a dry etchant.

20. The method of claim 1, wherein said removing comprises:
blanket exposing said wafer stack to radiation using said etched-back pattern reversal layer as a mask; and
contacting said raised features with a developer so as to remove said raised features.

21. The method of claim 1, wherein said transferring comprises etching said reversed pattern into said intermediate layers, if present, or into said substrate if no intermediate layers are present using said etched-back pattern reversal layer as a mask.

22. A microelectronic structure comprising:
a substrate having a surface;
one or more intermediate layers optionally formed on the substrate surface;
a pattern comprising a plurality of raised features on the intermediate layers, if present, or on the substrate surface if no intermediate layers are present, wherein said plurality of raised features are formed from a patterned imaging layer, said features each being defined by respective sidewalls and a top surface; and
a partially conformal pattern reversal layer adjacent said pattern, said pattern reversal layer being formed from a pattern reversal composition deposited between said plurality of features and overcoating said top surfaces of said plurality of features.

23. The structure of claim 22, wherein portions of said partially conformal layer adjacent said top surfaces of said raised features are partially cured.

24. The structure of claim 22, wherein the thickness of said partially conformal layer between said raised features is greater than the thickness of said partially conformal layer adjacent said top surfaces of said raised features.

25. The structure of claim 22, said raised features having a height, wherein the thickness of said partially conformal layer between said raised features is less than said height.

26. The structure of claim 22, wherein said partially conformal pattern reversal layer is not photosensitive.

27. The structure of claim 22, wherein said raised features have an average feature size of less than about 200 nm.
